(19) United States
(12) Patent Application Publication
(10) Pub. No.: US 2025/0323119 A1
(43) Pub. Date: Oct. 16, 2025

(54) THERMOELECTRIC COOLING STRUCTURE AT A HYBRID BONDING INTERFACE

(71) Applicant: International Business Machines Corporation, Armonk, NY (US)

(72) Inventors: Kishan Jayanand, COHOES, NY (US); Nicholas Alexander POLOMOFF, Hopewell Junction, NY (US); Viswas Purohit, East Amherst, NY (US); Nicholas Latham, Albanyq, NY (US); Ashim Dutta, Clifton Park, NY (US); Chih-Chao Yang, Glenmont, NY (US)

(21) Appl. No.: 18/631,800

(22) Filed: Apr. 10, 2024

(51) Int. Cl. H01L 23/38; H01L 23/00; H01L 23/48; H01L 25/065

(52) U.S. Cl. CPC H01L 23/38; H01L 23/481; H01L 24/08; H01L 25/0657; H01L 24/05; H01L 24/89; H01L 2224/05567; H01L 2224/0557; H01L 2224/08147; H01L 2225/06513; H01L 2225/06548; H01L 2225/06565

(57) ABSTRACT

A semiconductor device that includes a thermoelectric cooling structure at a hybrid bonding interface between two semiconductor dies is provided. Thermoelectric cooling structures that are formed at a hybrid bonding interface of two semiconductor dies can lead to enhanced thermal conductance, targeted thermal management, mitigated thermal expansion mismatch, extend operational reliability and/or provide integrated thermal management solutions.

### BACKGROUND

The present application relates to semiconductor technology, and more particularly to a semiconductor device that includes a thermoelectric cooling structure at a hybrid bonding interface.

Thermoelectric cooling has advantages of high reliability, no mechanical moving parts, compact in size and light in weight, and no working fluid. In addition, thermoelectric cooling has the advantage that it can be powered by direct current (DC) electric sources. Thermoelectric cooling uses the Peltier effect to create a heat flux at the junction of two different types of materials. A Peltier cooler is a solid-state active pump which transfers heat from one side of the device to the other, with consumption of electrical energy, depending on the direction of the current. Such a cooler can be referred to as a Peltier device or thermoelectric cooler (TEC).

Thermoelectric coolers operate by the Peltier effect (one of three phenomena that make up the thermoelectric effect). A thermoelectric module is made from three components; the conductors, legs, and the substrate, and many of these modules are connected electrically in series, but thermally in parallel. When a DC electric current flows through the device, it brings heat from one side to the other, so that one side gets cooler while the other gets hotter.

Thermoelectric cooling structures that operate on the Peltier effect include two semiconductors, one n-type and one p-type, as the conductive components. In a typical thermoelectric cooling structure, alternating p-type and n-type semiconductor pillars are placed thermally in parallel to each other and electrically in series and then they are joined with a thermally conducting plate on each side, usually ceramic, removing the need for a separate insulator. When a voltage is applied to the free ends of the two semiconductors, there is a flow of DC current across the junction of the semiconductors, causing a temperature difference. The side with the cooling plate absorbs heat which is then transported by the semiconductor to the other side of the device.

### SUMMARY

A semiconductor device that includes a thermoelectric cooling structure at a hybrid bonding interface between two semiconductor dies is provided. Thermoelectric cooling structures that are formed at a hybrid bonding interface of two semiconductor dies can lead to enhanced thermal conductance, targeted thermal management, mitigated thermal expansion mismatch, extend operational reliability and/or provide integrated thermal management solutions.

In one aspect of the present application, a semiconductor device is provided that includes a thermoelectric cooling structure. In one embodiment, the semiconductor device includes a top semiconductor die located above and in directly contacting a bottom semiconductor die, and a hybrid bonding interface is located between the top semiconductor die and the bottom semiconductor die. The top semiconductor die includes a top semiconductor-containing thermoelectric cooling element of a first conductivity type located on a first side of the hybrid bonding interface, and the bottom semiconductor die includes a bottom semiconductor-containing thermoelectric cooling element of a second conductivity type that is opposite from the first conductivity type located on a second side of the hybrid bonding interface which is opposite the first side of the hybrid bonding interface. In the semiconductor device, the top semiconductor-containing thermoelectric cooling element and the bottom semiconductor-containing thermoelectric cooling element are electrically connected to provide a thermoelectric cooling structure.

In another embodiment, the semiconductor device includes a top semiconductor die located above and in directly contacting a bottom semiconductor die, and a hybrid bonding interface is located between the top semiconductor die and the bottom semiconductor die. The top semiconductor die includes a top pillar-containing first semiconductor thermoelectric cooling element of a first conductivity type located on a first side of the hybrid bonding interface, and the bottom semiconductor die includes a bottom pillar-containing second semiconductor thermoelectric cooling element of a second conductivity type that is opposite from the first conductivity type located on a second side of the hybrid bonding interface which is opposite the first side of the hybrid bonding interface. In the semiconductor device, the top pillar-containing first semiconductor thermoelectric cooling element and the bottom pillar-containing second semiconductor thermoelectric cooling element are electrically connected to provide a thermoelectric cooling structure.

### BRIEF DESCRIPTION OF THE DRAWINGS

FIG. 1A is a cross sectional view of a first exemplary semiconductor die that can be employed in the present application, the first exemplary semiconductor die includes a first front-end-of-the-line (FEOL) level and a first back-end-of-the-line (BEOL) structure that includes first metal wiring embedded in a plurality of interconnect dielectric layers.

FIG. 1B is a cross sectional view of a second exemplary semiconductor die that can be employed in the present application, the second exemplary semiconductor die includes a second FEOL level and a second BEOL structure that includes second metal wiring embedded in a plurality of interconnect dielectric layers.

FIG. 2A is a cross sectional view of the first exemplary semiconductor die shown in FIG. 1A after forming first metal bond pads in a first bonding dielectric layer of the first semiconductor die.

FIG. 2B is a cross sectional view of the second exemplary semiconductor die shown in FIG. 1B after forming second metal bond pads in a second bonding dielectric layer of the second semiconductor die.

FIG. 3A is a cross sectional view of the first exemplary semiconductor die shown in FIG. 2A after forming a first semiconductor-containing thermoelectric cooling element of a first conductivity type in the first bonding dielectric layer of the first semiconductor die.

FIG. 3B is a cross sectional view of the second exemplary semiconductor die shown in FIG. 2B after forming a second semiconductor-containing thermoelectric cooling element of a second conductivity type in the second bonding dielectric layer of the second semiconductor die.

FIG. 4A is a cross sectional view of the first exemplary semiconductor die shown in FIG. 3A after forming individual first semiconductor-containing fingers of the first conductivity type, and forming a first dielectric material between each neighboring pairs of individual first semiconductor-containing fingers.

FIG. 4B is a cross sectional view of the second exemplary semiconductor die shown in FIG. 3B after forming individual second semiconductor-containing fingers of the second conductivity type, and forming a second dielectric material between each neighboring pairs of individual second semiconductor-containing fingers.

FIG. 5 is a cross sectional view of both the first and second exemplary semiconductor dies after flipping the first exemplary semiconductor die shown in FIG. 4A and aligning the flipped first exemplary semiconductor die over the second exemplary semiconductor die shown in FIG. 4B.

FIG. 6 is a cross sectional view of the flipped and aligned first exemplary semiconductor die and second exemplary semiconductor die shown in FIG. 5 after bringing the two exemplary semiconductor dies into intimate contact with each other and performing a bonding process to provide a semiconductor device having a thermoelectric cooling structure at a bonding interface between the two semiconductor dies in accordance with the present application.

FIG. 7 is a cross sectional view of the structure shown in FIG. 6 after further device processing.

FIG. 8A is a two dimensional (2D) illustration of a portion of the semiconductor device during the step of flipping the first exemplary semiconductor die and aligning the flipped first exemplary semiconductor die over the second exemplary semiconductor die.

FIG. 8B is a 2D illustration of the semiconductor device shown in FIG. 8A after hybrid bonding of the two semiconductor dies.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As stated above, a semiconductor device is provided that includes a thermoelectric cooling structure at a hybrid bonding interface between two semiconductor dies. Thermoelectric cooling structures that are formed at a hybrid bonding interface of two semiconductor dies can lead to enhanced thermal conductance, targeted thermal management, mitigated thermal expansion mismatch, extend operational reliability and/or provide integrated thermal management solutions.

Throughout the present application, the term “semiconductor die” denotes a block of a semiconducting material on which a given functional circuit is fabricated. The semiconductor material and the circuit are located in the front-end-of-the-line ((FEOL) level. The semiconducting material can include, for example, silicon (Si), a silicon germanium (SiGe) alloy, a silicon germanium carbide (SiGeC) alloy, germanium (Ge), III/V compound semiconductors or II/VI compound semiconductors. Typically, integrated circuits (ICs) are produced in large patches on a single semiconductor substrate (or wafer) through various processes that are well-known to those skilled in the art of IC fabrication. The substrate (or wafer) is then cut (i.e., diced) into many pieces, each containing a copy of the IC. Each of these pieces is called a semiconductor die (or die). The semiconductor die can also include a middle-of-the-line (MOL) level that includes MOL contact structures embedded in an interlayer dielectric (ILD) layer. The MOL level can be formed utilizing processes well-known in the art. The semiconductor die can also include a BEOL structure located above the MOL level. The MOL level and BEOL structure are formed prior to the cutting process.

Throughout the present application, the term “integrated circuit (or IC)” denotes an electronic device made up of multiple interconnect electronic components such, as, for example, transistors, resistors and capacitors. These components can be formed onto a semiconductor substrate utilizing any FEOL device process that is well-known to those skilled in the art of semiconductor device manufacturing.

Throughout the present application, the term “BEOL structure” denotes a structure including metal wires (i.e., metal lines and/or metal vias) embedded in multiple interconnect dielectric layers. Some of the metal wires of the BEOL structure can be used to interconnect with the ICs that are present at the FEOL level. The metal wires (i.e., metal lines and/or metal vias) are composed of an electrically conductive metal or an electrically conductive metal alloy. Illustrative examples of electrically conductive metals that can be used in forming the metal wires include, but are not limited to, Cu, Cu, Al, Co, Ru, Mo, Os, Ir, or Rh. An illustrative electrically conductive alloy that can be used in forming the metal wires includes, but is not limited to, a Cu—Al alloy. The interconnect dielectric layers of the BEOL structure (as well as the ILD layer mentioned above for the MOL level) include a dielectric material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The BEOL structure can be formed utilizing well-known BEOL processes including, for example, a damascene process or a subtractive etching process.

Throughout the present application, the term “thermoelectric cooling structure” denotes a cooling structure that includes Peltier (i.e., thermoelectric) cooling elements. Notably, the thermoelectric cooling structure includes a first conductivity type semiconductor region and a second conductivity type semiconductor region which are interconnected by various wiring regions. The first conductivity type semiconductor region is of a different conductivity type than the second conductivity type semiconductor region. In the present application, first conductivity type semiconductor region is located on a first side of a hybrid bonding interface and the second conductivity type semiconductor region is located on a second side of the hybrid bonding interface.

Throughout the present application, the term “hybrid bonding” denotes dielectric-to-dielectric bonding and metal-to-metal bonding such that a hybrid bonding interface is formed between the bonded dielectric materials and the bonded metals. Throughout the present application, the term “hybrid bonding interface” denotes an interface containing dielectric-to-dielectric bonding and metal-to-metal bonding.

In the description of the processing flow to follow, the term “first semiconductor die” can be used interchangeably with the term “top semiconductor die”, the term “first bonding dielectric layer” can be used interchangeably with the term “top bonding dielectric layer”, the term “first thermoelectric cooling element” can be used interchangeably with the term “top thermoelectric cooling element”, the term “second semiconductor die” can be used interchangeably with the term “bottom semiconductor die”, the term “second bonding dielectric layer” can be used interchangeably with the term “bottom bonding dielectric layer”, and the term “second thermoelectric cooling element” can be used interchangeably with the term “bottom thermoelectric cooling element”.

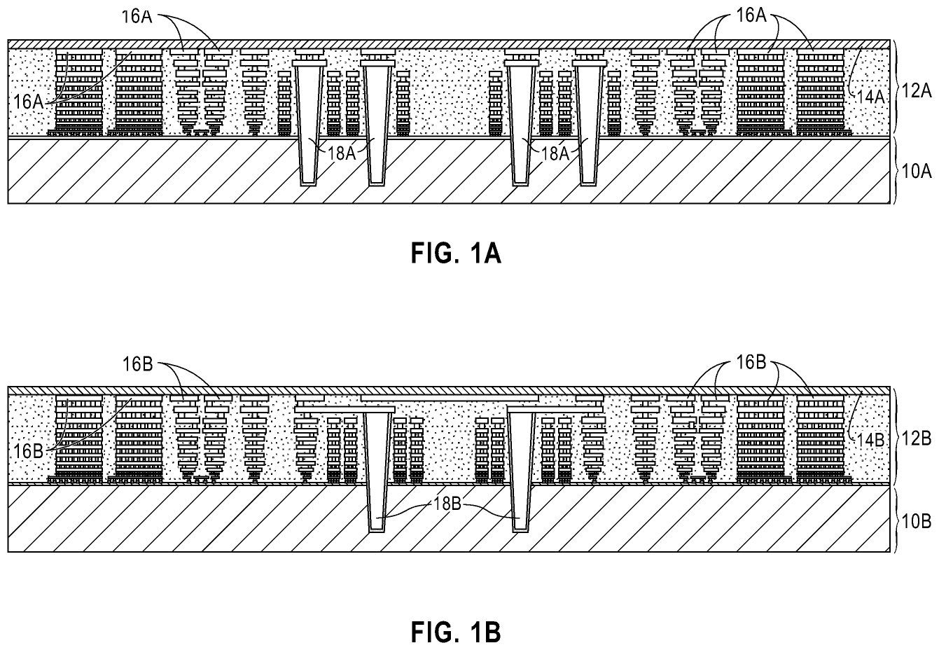

Referring to FIG. 1A, there is illustrated a first exemplary semiconductor die that can be employed in the present application. The first semiconductor die can be referred to as a top semiconductor die; and all the “first” components present in the first (i.e., top) semiconductor die can be referred to as “top” components. The first exemplary semiconductor die includes a first FEOL level 10A and a first BEOL structure 12A. The first BEOL structure 12A includes first metal wiring 16A embedded in a plurality of interconnect dielectric layers. The first FEOL level 10A includes a semiconducting material, as defined above, and an IC, as also defined above. A first MOL level (not specifically shown) can be located on top of the first FEOL level 10A. In the drawings, the semiconducting material and the IC of the first FEOL level 10A are not separately labeled, but each is meant to be included in the region denoted as the first FEOL level 10A.

The first BEOL structure 12A which is formed on top of the first FEOL level 10A includes a plurality of interconnect dielectric layers. The first BEOL structure 12A also includes a first bonding dielectric layer 14A as an uppermost dielectric layer of the first BEOL structure 12A. The first bonding dielectric layer 14A is composed of any bonding dielectric material such as, for example, tetraethyl orthosilicate (TEOS), silicon dioxide (SiO₂), silicon carbon nitride (SiCN) and/or carbon-doped silicon oxide (SiCOH). The first bonding dielectric layer 14A can be formed utilizing a deposition process including, for example, chemical vapor deposition (CVD), plasma enhanced chemical vapor deposition (PECVD), physical vapor deposition (PVD), or spin-on coating.

In FIG. 1A, the various interconnect dielectric layers that are beneath the first bonding dielectric layer 14A are not illustrated in the present application, but are intended to be included within the region denoted as the first BEOL structure 12A. Within the plurality of interconnect dielectric layers, first metal wires 16A are present. The first metal wires 16A can be connected to the IC within the first FEOL level 10A. The first metal wires 16A include metal vias and metal lines that are composed of an electrically conductive metal or electrically conductive metal alloy, both as defined above. First through via structures 18A are also present in a lower portion of the first BEOL structure 12A and they extend partially into the first FEOL level 10A of the first semiconductor die; typically the first through via structures 18A extend into the semiconducting material that provides the first FEOL level 10A. Some of the first metal wires 16A can be connected to the first through via structures 18A. The first through via structures 18A are composed of an electrically conductive metal or electrically conductive metal alloy, both as defined above, and they can be formed utilizing a metallization process that is well-known to those skilled in the art.

Referring now to FIG. 1B, there is illustrated a second exemplary semiconductor die that can be employed in the present application. The second semiconductor die can be referred to as a bottom semiconductor die; and all the “second” components present in the second (i.e., bottom) semiconductor die can be referred to as “bottom” components. The second exemplary semiconductor die includes a second FEOL level 10B and a second BEOL structure 12B. The second BEOL structure 12B includes second metal wiring 16B embedded in a plurality of interconnect dielectric layers. The second FEOL level 10B includes a semiconducting material, as defined above, and an IC, as defined above. A second MOL level (not specifically shown) can be located on top of the second FEOL level 10B. The semiconducting material and the IC of the second FEOL level 10B are not separately shown in the drawings of the present application, but each is meant to be included in the region denoted as the second FEOL level 10B. Second through via structures 18B are also present in a lower portion of the second BEOL structure 12B and they extend partially into the second FEOL level 10B of the second semiconductor die; typically the second through via structures 18B extend into the semiconducting material that provides the second FEOL level 10B. The second through via structure 18B are composed of an electrically conductive metal or electrically conductive metal alloy, both as defined above, and it can be formed utilizing a metallization process that is well-known to those skilled in the art.

The second BEOL structure 12B which is formed on top of the second FEOL level 10B includes a plurality of interconnect dielectric layers. The second BEOL structure 12B also includes a second bonding dielectric layer 14B as an uppermost dielectric layer of the second BEOL structure 12B. The second bonding dielectric layer 14B is composed of any bonding dielectric material such as, those mentioned above for the first bonding dielectric layer 14A. The second bonding dielectric layer 14B can be compositionally the same as, or compositionally different from, the first bonding dielectric layer 14A illustrated in FIG. 1A. The second bonding dielectric layer 14B can be formed utilizing a deposition process including, for example, CVD, PECVD, PVD, or spin-on coating. In FIG. 1B, the various interconnect dielectric layers that are beneath the second bonding dielectric layer 14B are not illustrated in the present application, but are intended to be included within the region denoted as the second BEOL structure 12B. Within the plurality of interconnect dielectric layers, second metal wires 16B are present. The second metal wires 16B include metal vias and metal lines that are composed of an electrically conductive metal or electrically conductive metal alloy, both as defined above. Some of the second metal wires 16B are connected to the IC that is present in the second FEOL level 10B. Other second metal wires 16B are connected to the second through via structures 18B.

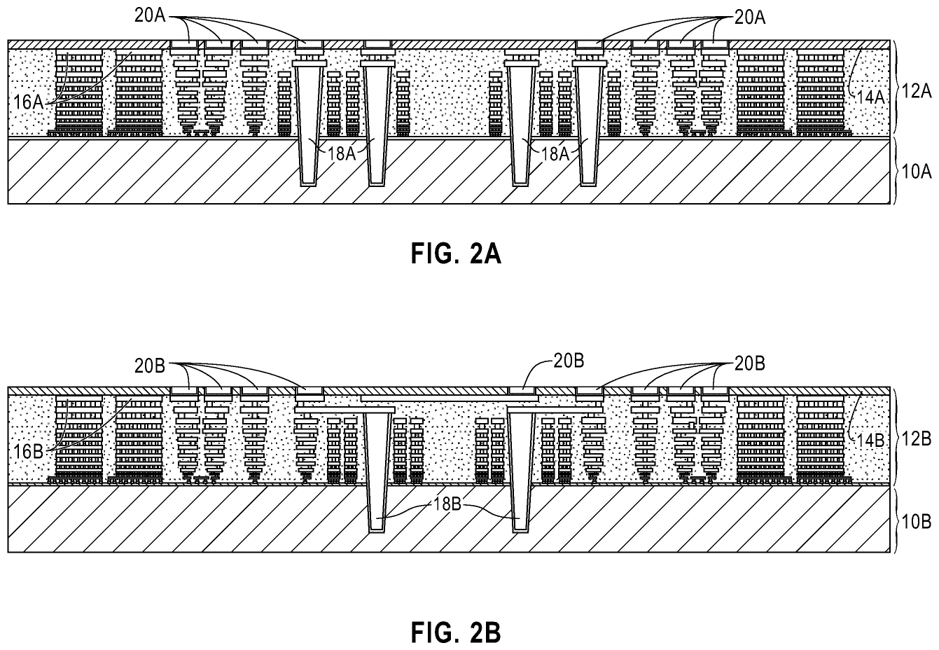

Referring now to FIG. 2A, there is illustrated the first exemplary semiconductor die shown in FIG. 1A after forming first metal bond pads 20A in the first bonding dielectric layer 14A of the first semiconductor die. As is illustrated, some of the first metal bond pads 20A are formed in contact with the first metal wires 16A that are in electrical contact with the first through via structures 18A, while other first metal bond pads 20A are formed in contact with other first metal wires 16A that are in electrical contact with the IC present in the first FEOL level 10A. The first metal bond pads 20A are composed of an electrically conductive metal or an electrically conductive metal alloy, as defined above. The first metal bond pads 20A can be formed utilizing a metallization process. The metallization process can include forming metal bond pads openings into the first bonding dielectric layer 14A. The metal bond pad openings can be formed by lithography and etching. Lithography includes forming (by a deposition process) a photoresist material on a layer or structure that needs to be patterned, exposing the as-deposited photoresist material to a desired pattern of irradiation, and developing the exposed photoresist material. The etching can include a dry etching process or a chemical wet etching process. Drying etching can include, for example, reactive ion etching (RIE), laser etching, or plasma etching. Wet etching includes the use of a chemical etchant. After forming the metal bond pads openings, the metallization process continues by filling the metal bond pads openings with an electrically conductive metal or an electrically conductive metal alloy, as defined above, and then a planarization process such as, for example, chemical mechanical polishing (CMP), is employed to remove any of the as-deposited electrically conductive material that is formed outside of the metal bond pads openings and on a topmost surface of the first bonding dielectric layer 14A. The depositing of the electrically conductive material can include, but is not limited to, CVD, PECVD, ALD, sputtering or plating.

Referring now to FIG. 2B, there is illustrated the second exemplary semiconductor die shown in FIG. 1B after forming second metal bond pads 20B in the second bonding dielectric layer 14B of the second semiconductor die. As is illustrated, some of the second metal bond pads 20B are formed in contact with the second metal wires 16B that are in electrical contact with the second through via structures 18, while other second metal bond pads 20B are formed in contact with other second metal wires 16B that are electrical contact with the IC that is present in the second FEOL level 10B. The second metal bond pads 20B are composed of an electrically conductive metal or an electrically conductive metal alloy, as defined above. The second metal bond pads 20B can be formed utilizing a metallization process, as defined above in forming the first metal bond pads 20A.

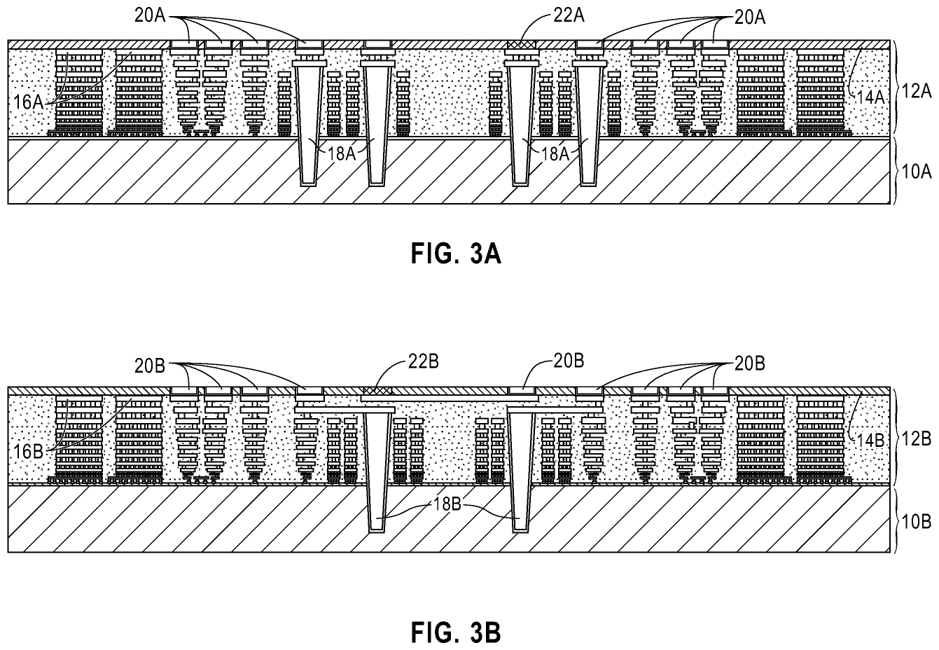

Referring now to FIG. 3A, there is illustrated the first exemplary semiconductor die shown in FIG. 2A after forming a first semiconductor-containing thermoelectric cooling element 22A of a first conductivity type in the first bonding dielectric layer 14A of the first semiconductor die. The first semiconductor-containing thermoelectric cooling element 22A includes a first semiconductor material and a first dopant. The first semiconductor material includes one of the semiconductor material mentioned above. The first dopant includes a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. The term “n-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, first semiconductor-containing thermoelectric cooling element 22A can have a dopant concentration of from 4×10²⁰ atoms/cm³ to 3×10²¹ atoms/cm³.

The first semiconductor-containing thermoelectric cooling element 22A is formed by forming a first semiconductor-containing thermoelectric cooling element opening in the first bonding dielectric layer 14A. The first semiconductor-containing thermoelectric cooling element opening physically exposes one of the first metal bond pads 20A that is in electrical contact with one of the first through via structures 18A. The first semiconductor-containing thermoelectric cooling element opening can be formed by lithography and etching, as defined above. The first semiconductor-containing thermoelectric cooling element opening is then filled with a first semiconductor material utilizing a deposition process such as, for example, CVD, PECVD or sputtering. In some embodiments, the first dopant can be formed at the same time as the first semiconductor material. In other embodiments, the first dopant can be introduced into an as-deposited undoped first semiconductor material utilizing any conventional process that can introduce a dopant into the as-deposited undoped first semiconductor material. In one example, the dopant can be introduced utilizing a dopant diffusion process that is well known to those skilled in the art. After deposition of the doped or undoped first semiconductor material a planarization process such as, for example, CMP can be used to provide the first semiconductor-containing thermoelectric cooling element 22A shown in FIG. 3A.

Referring now to FIG. 3B, there is illustrated the second exemplary semiconductor die shown in FIG. 2B after forming a second semiconductor-containing thermoelectric cooling element 22B of a second conductivity type in the second bonding dielectric layer 14B of the second semiconductor die. In the present application, the second conductivity type has an opposite conductivity than the first conductivity type. The second semiconductor-containing thermoelectric cooling element 22B includes a second semiconductor material and a second dopant. The second dopant is of an opposite conductivity type than the first dopant used in providing the first semiconductor-containing thermoelectric cooling element 22A. The second semiconductor material includes one of the semiconductor materials mentioned above. The second semiconductor material can be compositionally the same as, or compositionally different from, the first semiconductor material. The second dopant includes a p-type dopant or an n-type dopant, both as defined above. In one embodiment, the first semiconductor-containing thermoelectric cooling element 22A includes an n-type dopant, while the second semiconductor-containing thermoelectric cooling element 22B includes a p-type dopant. In another embodiment, the first semiconductor-containing thermoelectric cooling element 22A includes a p-type dopant, while the second semiconductor-containing thermoelectric cooling element 22B includes an n-type dopant. The second semiconductor-containing thermoelectric cooling element 22B can be formed utilizing the same techniques as mentioned above for forming the first semiconductor-containing thermoelectric cooling element 22A.

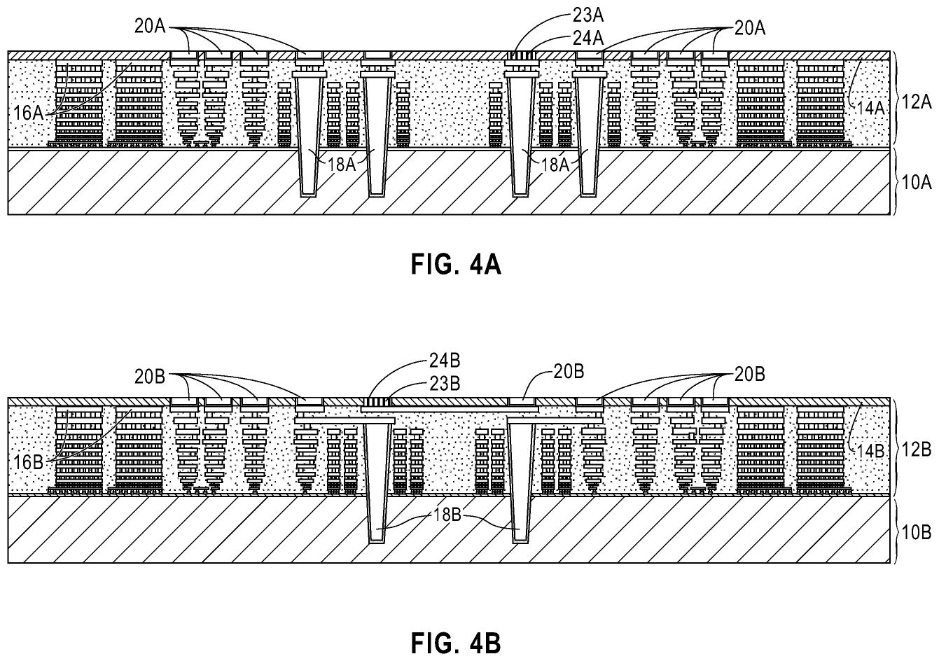

Referring now to FIG. 4A, there is illustrated the first exemplary semiconductor die shown in FIG. 3A after forming individual first semiconductor-containing fingers 23A of the first conductivity type and forming a first dielectric material 24A between each neighboring pairs of individual first semiconductor-containing fingers 23A. This step forms a top pillar-containing first semiconductor thermoelectric cooling element that contains the individual first semiconductor-containing fingers 23A of the first conductivity type that are spaced apart by first dielectric material 24A. This step is optional and can be omitted in some embodiments of the present application. The individual first semiconductor-containing fingers 23A are formed by lithography and etching of the first semiconductor-containing thermoelectric cooling element 22A shown in FIG. 3A. The first dielectric material 24A includes any dielectric material such as, for example, silicon dioxide. The first dielectric material 24A can be formed by a deposition process (such as, for example, CVD, PECVD, or ALD), followed by a planarization process such as, for example, CMP. The first dielectric material 24A and the individual first semiconductor-containing fingers 23A have topmost surfaces that are substantially coplanar with each other and topmost surfaces that are substantially coplanar with the first bonding dielectric layer 14A.

Referring now to FIG. 4B, there is illustrated the second exemplary semiconductor die shown in FIG. 3B after forming individual second semiconductor-containing fingers 23B of the second conductivity type and forming a second dielectric material 24B between each neighboring pairs of individual second semiconductor-containing fingers 23B. This step forms a bottom pillar-containing second semiconductor thermoelectric cooling element that contains the individual second semiconductor-containing fingers 23B of the second conductivity type that are spaced apart by second dielectric material 24B. This step is optional and can be omitted in some embodiments of the present application. Note that this step is typically, but not necessarily always, performed when a pillar-containing first semiconductor thermoelectric cooling element is formed. In some embodiments, the pillar-containing second semiconductor thermoelectric cooling element is not formed, but the pillar-containing first semiconductor thermoelectric cooling element is formed. In other embodiments, the pillar-containing second semiconductor thermoelectric cooling element is formed, but the pillar-containing first semiconductor thermoelectric cooling element is not formed. The individual second semiconductor-containing fingers 23B are formed by lithography and etching of the second semiconductor-containing thermoelectric cooling element 22B shown in FIG. 3B. The second dielectric material 24B includes any dielectric material such as, for example, silicon dioxide. The second dielectric material 24B can be composed of a compositionally same dielectric material as, or a compositionally different dielectric material than, the first dielectric material 24A. The pillar-containing second semiconductor-containing thermoelectric cooling element can be formed utilizing the same technique as mentioned above for forming the pillar-containing first thermoelectric cooling element. The second dielectric material 24B and the individual second semiconductor-containing fingers 23B have topmost surfaces that are substantially coplanar with each other and topmost surfaces that are substantially coplanar with the second bonding dielectric layer 14B. The pillar-containing semiconductor-containing thermoelectric cooling elements can provide enhanced cooling (greater surface area in which cooling can occur).

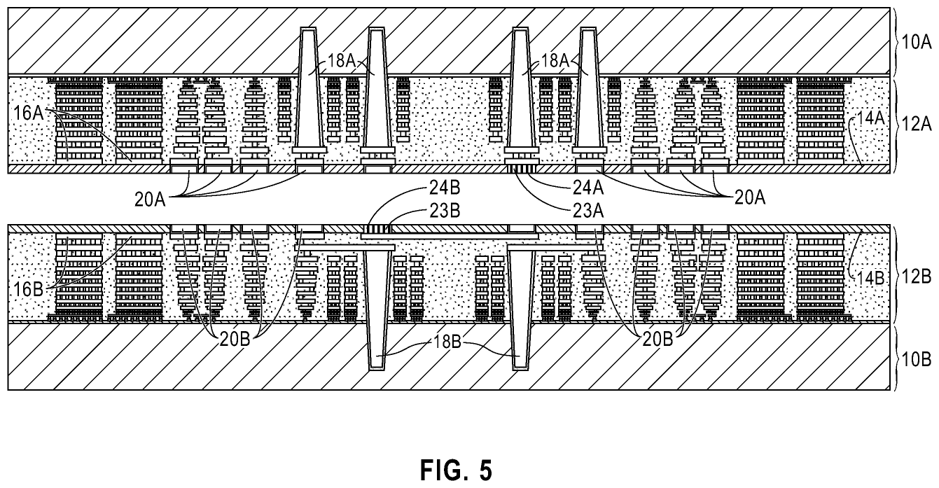

Referring now to FIG. 5, there is illustrated both the first and second exemplary semiconductor dies after flipping the first exemplary semiconductor die shown in FIG. 4A and aligning the flipped first exemplary semiconductor die over the second exemplary semiconductor die shown in FIG. 4B. Flipping, aligning and subsequent bonding can also be formed utilizing the two semiconductor dies shown in FIGS. 3A-3B In the present application, the first exemplary semiconductor die shown in FIG. 4A is flipped 180° such that the first FEOL level 10A is now located on top of the first BEOL structure 12A. Flipping can be performed by hand or by utilizing a mechanical means such as, for example, a robot arm. The aligning includes positioning the flipped first exemplary semiconductor die over the second exemplary semiconductor die shown in FIG. 4B such that the region including the top pillar-containing first semiconductor thermoelectric cooling element (or alternatively, the first semiconductor-containing thermoelectric cooling element 22A shown in FIG. 3A) is located over one of the second metal bond pads 20B, and such that the bottom pillar-containing second semiconductor thermoelectric cooling element (or alternatively, the second semiconductor-containing thermoelectric cooling element 22B shown in FIG. 3B) is located beneath one of the first metal bond pads 20A.

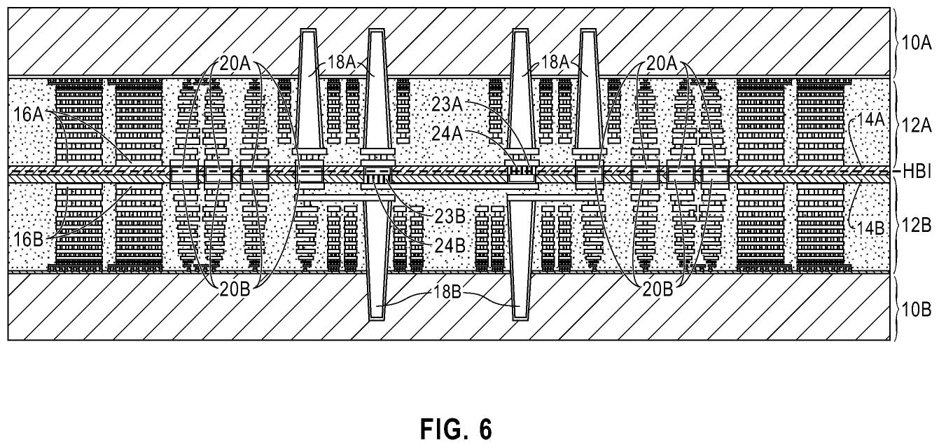

Referring now to FIG. 6, there is now illustrated the flipped and aligned first exemplary semiconductor die and second exemplary semiconductor die shown in FIG. 5 after bringing the two exemplary semiconductor dies into intimate contact with each other and performing a bonding process to provide a semiconductor device having a thermoelectric cooling structure in accordance with the present application. The bringing the two exemplary semiconductor dies into intimate contact with each other can include the application of an external force which may or may not remain during the actual bonding process. The bonding process (which can also be referred to a hybrid bonding process) includes metal-to-metal bonding and dielectric-to-dielectric bonding. The bonding process includes heating the intimately contacted and aligned structures from room temperature (i.e., 20° C.-25° C.) up to 350° C.; other bonding temperatures can be used. The bonding process is typically performed in an inert ambient such as, for example, He, Ar, Ne or mixtures thereof. After bonding, the temperature can be lowered back to room temperature. The bonding process can also include an activation process as described below.

Hybrid bonding refers to a 3D packing technique to connect semiconductor builds. Hybrid bonding forms connections of semiconductor structures through metal pads which are embedded in a dielectric layer at a bond interface on each semiconductor structure that is being bonded. The dielectric layer at bond interface include, but is not necessarily limited to, TEOS, SiO₂, SiCN, and/or SiCOH. The metal pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. Hybrid bonding process itself includes alignment to control the overlay of metal pads and to ensure electrical continuity between semiconductor build undergoing hybrid bonding process, mating of dielectric/metal pad surfaces, annealing under a set pressure. The anneal process of the mated semiconductor builds ensures formation of covalent bonds between the dangling bonds across the dielectric surfaces of opposing semiconductor builds, as well as reflow (melting and joining) of the metal pads between the surfaces of opposing semiconductor builds to ensure electrical conductivity. The covalent bonds formed between the dielectric surfaces, and the joining of metal pads as a result of reflow process ensures that hybrid bonding interfaces joins two semiconductor builds and also ensures that there is electrical continuity between them. The dangling bonds and covalent bonding occurs in the present application.

Notably, and in the present application, the bonding process bonds (i.e., connects) the top pillar-containing first semiconductor thermoelectric cooling element (or alternatively, the first semiconductor-containing thermoelectric cooling element 22A shown in FIG. 3A) to one of the second metal bond pads 20B, and bonds (i.e., connects) the bottom pillar-containing second semiconductor thermoelectric cooling element (or alternatively, the second semiconductor-containing thermoelectric cooling element 22B shown in FIG. 3B) to one of the first metal bond pads 20A. The connections occur at a bonding interface, HBI, as shown in FIG. 6. Notably, the HBI is located between the first bonding dielectric layer 14A and the second bonding dielectric layer 14B, between top pillar-containing first semiconductor thermoelectric cooling element (or alternatively, the first semiconductor-containing thermoelectric cooling element 22A shown in FIG. 3A) and one of the second metal bond pads 20B, and between the bottom pillar-containing second semiconductor thermoelectric cooling element (or alternatively, the second semiconductor-containing thermoelectric cooling element 22B shown in FIG. 3B) and one of the first metal bond pads 20A. The HBI thus contains metal-to-metal bonding and dielectric-to-dielectric bonding.

The bonding process thus forms a semiconductor device including a thermoelectric cooling structure at the HBI between the first semiconductor die and the second semiconductor die. In some embodiments, the thermoelectric cooling structure can include the pillar-containing first semiconductor thermoelectric cooling element and the pillar-containing second semiconductor thermoelectric cooling element. In other embodiments, the thermoelectric cooling structure can include the first semiconductor-containing thermoelectric cooling element 22A and the second semiconductor-containing thermoelectric cooling element 22B. Embodiments exists in which the thermoelectric cooling structure includes the pillar-containing first semiconductor thermoelectric cooling element and the second semiconductor-containing thermoelectric cooling element 22B, or the pillar-containing second semiconductor thermoelectric cooling element and the first semiconductor-containing thermoelectric cooling element 22A. As is shown, a first (i.e., top) portion of the thermoelectric cooling structure is formed on a first side of the HBI, while a second (bottom) portion of the thermoelectric cooling structure is formed on a second side, which is opposite the first side of the HBI.

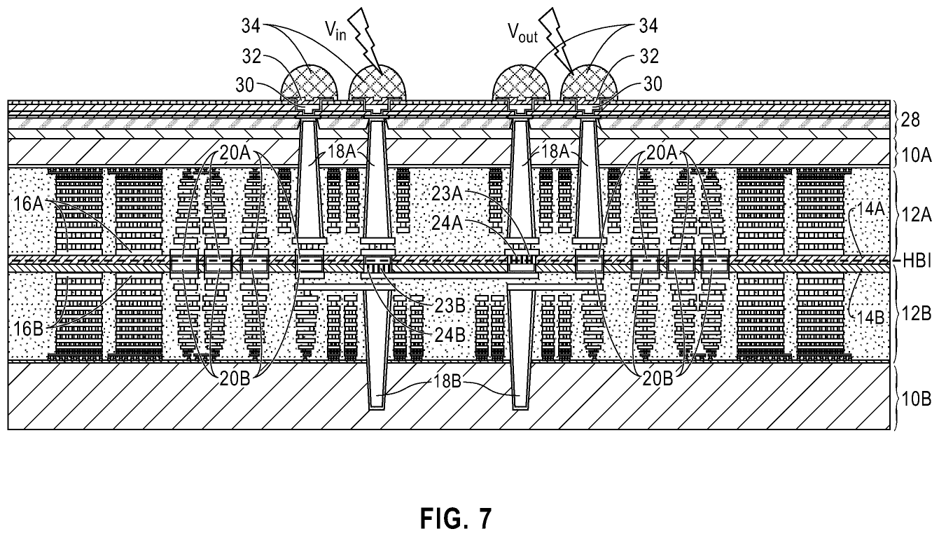

Referring now to FIG. 7, there is illustrated the structure shown in FIG. 6 after further device processing. The further device process includes first thinning the first semiconductor die by a planarization process including, for example, CMP and/or grinding, to physically expose a surface of each first through via structure 18A that is embedded in the semiconducting material of the first FEOL level 10A. Various grindside dielectric layers 28 are then formed, followed by the formation of metal bond pads 30 and under bump metal structures 32, and thereafter solder bump 34 formation. The various grindside dielectric layers 28 include any dielectric material such as, for example, silicon dioxide, silicon nitride and/or silicon oxynitride. Each of the grindside dielectric layers 28 is formed utilizing a deposition process such as, for example, CVD, PECVD, PVD, or ALD. Metal bond pads 30 are formed utilizing a metallization process as defined above. The under bump metal structures 32 are then formed utilizing another metallization process, and thereafter solder bumps 34 are formed by deposition of a solder on the under bump metal structures 32.

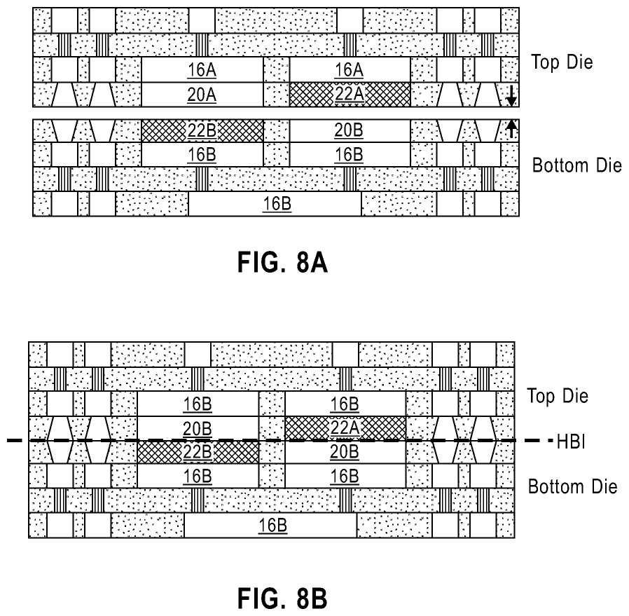

Referring now to FIG. 8A, there is provided a 2D illustration of a portion of the exemplary semiconductor device of the present application (prior to bonding), and FIG. 8B is a 2D illustration of a portion of the exemplary device after bonding. The semiconductor device illustrated in FIG. 8B includes a thermoelectric cooling structure in accordance with the present application.

In one aspect of the present application, a semiconductor device is provided that includes a thermoelectric cooling structure. In one embodiment, the semiconductor device includes a top semiconductor die located above and in directly contacting a bottom semiconductor die, and a hybrid bonding interface HBI is located between the top semiconductor die and the bottom semiconductor die. The top semiconductor die includes a top semiconductor-containing thermoelectric cooling element (i.e., first semiconductor-containing thermoelectric cooling element 22A) a first conductivity type located on a first side of the hybrid bonding interface HBI, and the bottom semiconductor die includes a bottom semiconductor-containing thermoelectric cooling element (i.e., second semiconductor-containing thermoelectric cooling element 22B) of a second conductivity type that is opposite from the first conductivity type located on a second side of the hybrid bonding interface HBI which is opposite the first side of the hybrid bonding interface HBI. In the semiconductor device, the top semiconductor-containing thermoelectric cooling element (i.e., first semiconductor-containing thermoelectric cooling element 22A) and the bottom semiconductor-containing thermoelectric cooling element (i.e., second semiconductor-containing thermoelectric cooling element 22B) are electrically to provide a thermoelectric cooling structure. Such thermoelectric cooling structures at the hybrid bonding interface HBI is of significance, since stacking of dies leads to poor heat transfer from bond interface to external cooling elements. Furthermore, hot spots at the hybrid bonding interface poses reliability issues such as, but not limited to, electromigration, diffusion of Cu in the surrounding low-k dielectric material, thermal stresses from differences in thermal expansion coefficients of dielectric material and metal elements at bond interface, and crack propagation. Incorporation of thermoelectric cooling element at the bond interface effectively pumps hot stops from FEOL and external cooling elements, improving the reliability of the hybrid bonding interface.

In embodiments of the present application, the device further includes top metal wiring (i.e., first metal wiring 16A) located in the top semiconductor die and bottom metal wiring (i.e., second metal wiring 16B) located in the bottom semiconductor die, wherein the top metal wiring and the bottom metal wiring are used to electrically connect the top semiconductor-containing thermoelectric cooling element and the bottom semiconductor-containing thermoelectric cooling element.

In some embodiments of the present application, the first conductivity type is n-type, and the second conductivity type is p-type.

In some embodiments of the present application, the first conductivity type is p-type, and the second conductivity type is n-type.

In some embodiments of the present application, the semiconductor device further includes a pair of through via structures (i.e., first through via structures 18A) located in the top semiconductor die, wherein a first through via structure of the pair of through via structures is electrically connected to the top semiconductor-containing thermoelectric cooling element (i.e., first semiconductor-containing thermoelectric cooling element 22A) and a second through via structure of the pair of through via structures is electrically connected to the bottom semiconductor-containing thermoelectric cooling element (i.e., second semiconductor-containing thermoelectric cooling element 22B).

In some embodiments of the present application, the hybrid bonding interface includes metal-to-metal bonding and dielectric-to-dielectric bonding.

In some embodiments of the present application, the top semiconductor-containing thermoelectric cooling element (i.e., first semiconductor-containing thermoelectric cooling element 22A) is present in a top bonding dielectric layer (i.e., first dielectric layer 14A) of the top semiconductor die, and the bottom semiconductor-containing thermoelectric cooling element (i.e., second semiconductor-containing thermoelectric cooling element 22B) is present in a bottom bonding dielectric layer (i.e., second bonding dielectric layer 14B) of the bottom semiconductor die, and the top bonding dielectric layer and the bottom bonding layer have a dielectric-to-dielectric bond at the hybrid bonding interface HBI.

In some embodiments of the present application, the top semiconductor die includes a top FEOL level (i.e., first FEOL level 10A) and a top BEOL structure (i.e., first BEOL structure 12A) including a top bonding dielectric layer (i.e., first bonding dielectric layer 14A) as an uppermost layer, and the bottom semiconductor die includes a bottom FEOL level (i.e., second FEOL level 10B) and a bottom BEOL structure (i.e., second BEOL structure 12B) including a bottom bonding dielectric layer (i.e., the second bonding dielectric layer 14B) as the uppermost, wherein the top bonding dielectric layer and the bottom bonding layer have a dielectric-to-dielectric bond at the hybrid bonding interface.

In another embodiment, the semiconductor device includes a top semiconductor die located above and in directly contacting a bottom semiconductor die, and a hybrid bonding interface HBI is located between the top semiconductor die and the bottom semiconductor die. The top semiconductor die includes a top pillar-containing first semiconductor thermoelectric cooling element (i.e., first semiconductor-containing fingers 23A and the first dielectric material 24A) of a first conductivity type located on a first side of the hybrid bonding interface HBI, and the bottom semiconductor die includes a bottom pillar-containing second semiconductor thermoelectric cooling element (i.e., second semiconductor-containing fingers 23B and the second dielectric material 24B) including of a second conductivity type that is opposite from the first conductivity type located on a second side of the hybrid bonding interface HBI which is opposite the first side of the hybrid bonding interface HBI. In the semiconductor device, the top pillar-containing first semiconductor thermoelectric cooling element and the bottom pillar-containing second semiconductor thermoelectric cooling element are electrically connected to provide a thermoelectric cooling structure. Pillar configuration of the thermoelectric cooling elements essentially increases the surface area of the semiconductors forming the thermoelectric junction, resulting in a better thermoelectric performance in a relatively smaller real estate within the hybrid bonding junction.

In embodiments, the device further includes top metal wiring (i.e., first metal wiring 16A) located in the top semiconductor die and bottom metal wiring (i.e., second metal wiring 16B) located in the bottom semiconductor die, wherein the top metal wiring and the bottom metal wiring are used to electrically connect the top pillar-containing first semiconductor thermoelectric cooling element and the bottom pillar-containing second semiconductor thermoelectric cooling element.

In some embodiments of the present application, the first conductivity type is n-type, and the second conductivity type is p-type.

In some embodiments of the present application, the first conductivity type is p-type, and the second conductivity type is n-type.

In some embodiments of the present application, the semiconductor device further includes a pair of through via structures (i.e., first through via structures 18A) located in the top semiconductor die, wherein a first through via structure of the pair of through via structures is electrically connected to the top pillar-containing first semiconductor thermoelectric cooling element (i.e., first semiconductor-containing fingers 23A and the first dielectric material 24A) and a second through via structure of the pair of through via structures is electrically connected to the bottom pillar-containing second semiconductor thermoelectric cooling element (i.e., second semiconductor-containing fingers 23B and the second dielectric material 24B).

In embodiments of the present application, the hybrid bonding interface includes metal-to-metal bonding and dielectric-to-dielectric bonding.

In some embodiments of the present application, the top pillar-containing first semiconductor thermoelectric cooling element (i.e., first semiconductor-containing fingers 23A and the first dielectric material 24A) is present in a top bonding dielectric layer (i.e., first bonding dielectric layer 14A) of the top semiconductor die, and the bottom pillar-containing second semiconductor thermoelectric cooling element (i.e., second semiconductor-containing fingers 23B and the second dielectric material 24B) is present in a bottom bonding dielectric layer (i.e., the second bonding dielectric layer 14B) of the bottom semiconductor die, and the top bonding dielectric layer and the bottom bonding layer have a dielectric-to-dielectric bond at the hybrid bonding interface.

In some embodiments of the present application, the top semiconductor die includes a top FEOL level (i.e., first FEOL level 10A) and a top BEOL structure (i.e., first BEOL structure 12A) including a top bonding dielectric layer (i.e., first bonding dielectric layer 14A) as an uppermost layer, and the bottom semiconductor die includes a bottom FEOL level (i.e., second FEOL level 10B) and a bottom BEOL structure (i.e., second BEOL structure 12B) including a bottom bonding dielectric layer (i.e., the second bonding dielectric layer 14B) as the uppermost, wherein the top bonding dielectric layer and the bottom bonding layer have a dielectric-to-dielectric bond at the hybrid bonding interface.

In some embodiments of the present application, the top pillar-containing first semiconductor thermoelectric cooling element comprises a plurality of individual top semiconductor-containing fingers (i.e., first semiconductor-containing fingers 23A) that are spaced apart by a first dielectric material 24A).

In some embodiments of the present application, the bottom pillar-containing second semiconductor thermoelectric cooling element comprises a plurality of individual bottom semiconductor-containing fingers (i.e., second semiconductor-containing fingers 23B that are spaced apart by a second dielectric material 24B).

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a top semiconductor die located above and directly contacting a bottom semiconductor die; and
a hybrid bonding interface located between the top semiconductor die and the bottom semiconductor die, wherein the top semiconductor die comprises a top semiconductor-containing thermoelectric cooling element of a first conductivity type located on a first side of the hybrid bonding interface, and the bottom semiconductor die comprises a bottom semiconductor-containing thermoelectric cooling element of a second conductivity type that is opposite from the first conductivity type located on a second side of the hybrid bonding interface which is opposite the first side of the hybrid bonding interface, wherein the top semiconductor-containing thermoelectric cooling element and the bottom semiconductor-containing thermoelectric cooling element are electrically connected to provide a thermoelectric cooling structure.

2. The semiconductor device of claim 1, further comprising top metal wiring located in the top semiconductor die and bottom metal wiring located in the bottom semiconductor die, wherein the top metal wiring and the bottom metal wiring are used to electrically connect the top semiconductor-containing thermoelectric cooling element and the bottom semiconductor-containing thermoelectric cooling element.

3. The semiconductor device of claim 1, wherein the first conductivity type is n-type, and the second conductivity type is p-type.

4. The semiconductor device of claim 1, wherein the first conductivity type is p-type, and the second conductivity type is n-type.

5. The semiconductor device of claim 1, further comprising a pair of through via structures located in the top semiconductor die, wherein a first through via structure of the pair of through via structures is electrically connected to the top semiconductor-containing thermoelectric cooling element and a second through via structure of the pair of through via structures is electrically connected to the bottom semiconductor-containing thermoelectric cooling element.

6. The semiconductor device of claim 1, wherein the hybrid bonding interface comprises metal-to-metal bonding and dielectric-to-dielectric bonding.

7. The semiconductor device of claim 1, wherein the top semiconductor-containing thermoelectric cooling element is present in a top bonding dielectric layer of the top semiconductor die, and the semiconductor-containing thermoelectric cooling element is present in a bottom bonding dielectric layer of the bottom semiconductor die, and the top bonding dielectric layer and the bottom bonding layer have a dielectric-to-dielectric bond at the hybrid bonding interface.

8. The semiconductor device of claim 1, wherein the top semiconductor die comprises a top front-end-of-the-line (FEOL) level and a top back-end-of-the-line (BEOL) structure including a top bonding dielectric layer as an uppermost layer, and the bottom semiconductor die comprises a bottom FEOL level and a bottom BEOL structure including a bottom bonding dielectric layer as an uppermost layer, wherein the top bonding dielectric layer and the bottom bonding layer form a dielectric-to-dielectric bond at the hybrid bonding interface.

9. A semiconductor device comprising:
a top semiconductor die located above and directly contacting a bottom semiconductor die; and
a hybrid bonding interface located between the top semiconductor die and the bottom semiconductor die, wherein the top semiconductor die comprises a top pillar-containing first semiconductor thermoelectric cooling element of a first conductivity type located on a first side of the hybrid bonding interface, and the bottom semiconductor die comprises a bottom pillar-containing second semiconductor thermoelectric cooling element of a second conductivity type that is opposite from the first conductivity type located on a second side of the hybrid bonding interface which is opposite the first side of the hybrid bonding interface, and the top pillar-containing first semiconductor thermoelectric cooling element and the bottom pillar-containing second semiconductor thermoelectric cooling element are electrically connected to provide a thermoelectric cooling structure.

10. The semiconductor device of claim 9, further comprising top metal wiring located in the top semiconductor die and bottom metal wiring located in the bottom semiconductor die, wherein the top metal wiring and the bottom metal wiring are used to electrically connect the top pillar-containing first semiconductor thermoelectric cooling element and the bottom pillar-containing second semiconductor thermoelectric cooling element.

11. The semiconductor device of claim 9, wherein the first conductivity type is n-type, and the second conductivity type is p-type.

12. The semiconductor device of claim 9, wherein the first conductivity type is p-type, and the second conductivity type is n-type.

13. The semiconductor device of claim 9, further comprising a pair of through via structures located in the top semiconductor die, wherein a first through via structure of the pair of through via structures is electrically connected to the top pillar-containing first semiconductor thermoelectric cooling element and a second through via structure of the pair of through via structures is electrically connected to the bottom pillar-containing second semiconductor thermoelectric cooling element.

14. The semiconductor device of claim 9, wherein the hybrid bonding interface comprises metal-to-metal bonding and dielectric-to-dielectric bonding.

15. The semiconductor device of claim 9, wherein the top pillar-containing first semiconductor thermoelectric cooling element is present in a top bonding dielectric layer of the top semiconductor die, and the bottom pillar-containing second semiconductor thermoelectric cooling element is present in a bottom bonding dielectric layer of the bottom semiconductor die, and the top bonding dielectric layer and the bottom bonding layer have a dielectric-to-dielectric bond at the hybrid bonding interface.

16. The semiconductor device of claim 9, wherein the top semiconductor die comprises a top front-end-of-the-line (FEOL) level and a top back-end-of-the-line (BEOL) structure including a top bonding dielectric layer as an uppermost layer, and the bottom semiconductor die comprises a bottom FEOL level and a bottom BEOL structure including a bottom bonding dielectric layer as an uppermost layer, wherein the top bonding dielectric layer and the bottom bonding layer form a dielectric-to-dielectric bond at the hybrid bonding interface.

17. The semiconductor device of claim 9, wherein the top pillar-containing first semiconductor thermoelectric cooling element comprises a plurality of individual top semiconductor-containing fingers that are spaced apart by a first dielectric material.

18. The semiconductor device of claim 9, wherein the bottom pillar-containing second semiconductor thermoelectric cooling element comprises a plurality of individual bottom semiconductor-containing fingers that are spaced apart by a second dielectric material.
